(19) United States
(12) Patent Application Publication
(10) Pub. No.: US 2023/0043448 A1
(43) Pub. Date: Feb. 9, 2023

(54) DETECTION CIRCUIT AND CONTROL METHOD THEREOF

(71) Applicant: Egis Technology Inc., Hsinchu City (TW)

(72) Inventors: Chung-Yi Wang, Hsinchu County (TW); Yu-Hsuan Lin, Hsinchu County (TW); Tzu-Li Hung, Hsinchu County (TW)

(73) Assignee: Egis Technology Inc., Hsinchu City (TW)

(21) Appl. No.: 17/792,410

(22) PCT Filed: Aug. 19, 2020
(86) PCT No.: PCT/CN2020/109982

§ 371 Date: Jul. 13, 2022

Related U.S. Application Data
(60) Provisional application No. 62/960,152, filed on Jan. 13, 2020.

(51) Int. Cl. G06V 40/13; H03K 17/96

(52) U.S. Cl. CPC G06V 40/1306; H03K 17/962

(57) ABSTRACT

A detection circuit includes a first detection terminal, a second detection terminal, a first switch, a second switch, a first capacitor, a second capacitor and an amplifier. The first switch is coupled to the first detection terminal. The second switch is coupled to the second detection terminal. The first capacitor is coupled between the first switch and the second switch. The amplifier includes a first input terminal coupled to the second switch, a second input terminal used to receive an operation signal, and an output terminal used to output an output signal. The second capacitor is coupled between the first input terminal and the output terminal of the amplifier. The first switch and the second switch are turned on alternatively.

### CROSS REFERENCE TO RELATED APPLICATIONS

This application claims priority to U.S. Provisional Application No. 62/960,152, filed on Jan. 13, 2020, and incorporated herein by reference in its entirety.

### BACKGROUND OF THE INVENTION

### 1. Field of the Invention

The disclosure is related to a detection circuit and a control method, and more particularly, a detection circuit and a control method used for finger detection and touch detection.

### 2. Description of the Prior Art

With the increasing popularity of consumer electronic products, applications of touch detection are more and more common. For example, users can send commands and input text by touching the displays of smart phones or tablets. In addition, machines such as automatic teller machines (ATMs) can use the touch interfaces to omit the physical keyboard.

At the same time, as users' demands for security continue to increase, the related applications of fingerprint detection are increasing. For example, when a user wants to operate an electronic device, the user can place a finger on a specific interface to perform fingerprint detection to confirm the identity.

In common scenarios, users can touch devices and perform fingerprint detection through screens or specific interfaces. At present, in order to achieve touch detection and fingerprint detection, two dedicated detection circuits must be used to detect fingerprints and touches respectively. Therefore, the complexity and the area of the circuit cannot be reduced, the control process is complicate, and integrating the interfaces is a difficult task.

### SUMMARY OF THE INVENTION

An embodiment provides a detection circuit including a first detection terminal, a second detection terminal, a first switch, a second switch, a first capacitor, an amplifier and a second capacitor. The first detection terminal is used to receive a first signal. The second detection terminal is used to receive a second signal. The first switch is coupled to the first detection terminal. The second switch is coupled to the second detection terminal. The first capacitor is coupled to the first switch and the second switch. The amplifier includes a first input terminal coupled to the first capacitor, a second input terminal for receiving an operating signal, and an output terminal for outputting an output signal. The second capacitor is coupled between the first input terminal and the output terminal of the amplifier. The first switch and the second switch are turned on alternatively.

Another embodiment provides a control method for a detection circuit. The detection circuit includes a first detection terminal, a second detection terminal, a first switch, a second switch, a first capacitor, a second capacitor and an amplifier. The first switch is coupled between the first detection terminal and the first capacitor. The second switch is coupled between the second detection terminal and the first capacitor. The first capacitor is coupled between the first switch and a first input terminal of the amplifier. The second capacitor is coupled between the first input terminal and an output terminal of the amplifier. The second input terminal of the amplifier is used for receiving an operating signal. The control method includes turning off the first switch and turning on the second switch for receiving a second signal through the second detection terminal and the second switch during a first period, and turning on the first switch and turning off the second switch for receiving a first signal through the first detection terminal and the first switch during a second period.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a detection circuit performing fingerprint detection according to an embodiment.

FIG. 2 illustrates the detection circuit performing touch detection according to an embodiment.

FIG. 3 illustrates the detection circuit performing the display function according to an embodiment.

FIG. 4 illustrates the operation modes and the waveform of the operating signal of the detection circuit shown in FIG. 1 to FIG. 3.

FIG. 5 is a flowchart of a control method for the detection circuit in FIG. 1 to FIG. 3 according to an embodiment.

### DETAILED DESCRIPTION

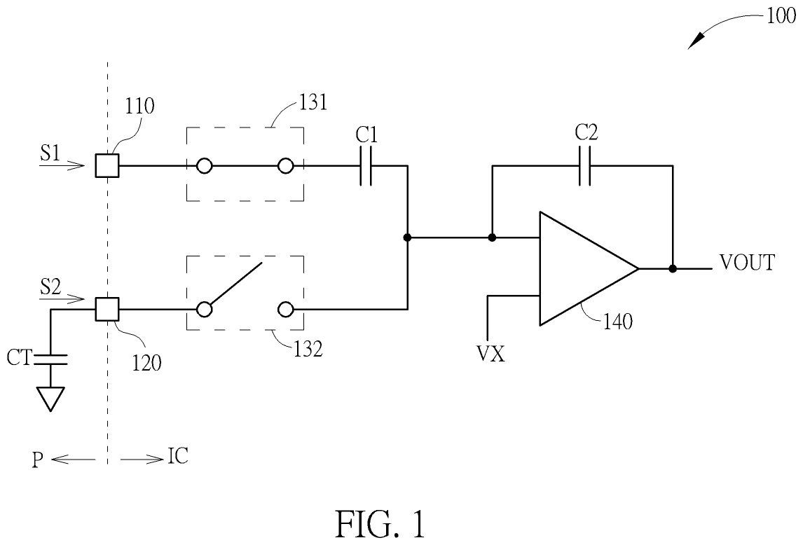

FIG. 1 illustrates a detection circuit 100 according to an embodiment. The detection circuit 100 can include a first detection terminal 110, a second detection terminal 120, a first switch 131, a second switch 132, a first capacitor C1, a second capacitor C2 and an amplifier 140.

The first detection terminal 110 can receive a first signal S1. The second detection terminal 120 can receive a second signal S2. The first switch 131 can be coupled to the first detection terminal 110. The second switch 132 can be coupled to the second detection terminal 120.

The first capacitor C1 is coupled to the first switch 131 and the second switch 132. The amplifier 140 can include a first input terminal, a second input terminal and an output terminal, where the first input terminal can be coupled to the first capacitor C1, the second input terminal can receive an operating signal VX, and the output terminal can output an output signal VOUT. The second capacitor C2 can be coupled between the first input terminal and the output terminal of the amplifier 140.

As shown in FIG. 1, the first switch 131, the second switch 132, the first capacitor C1, the second capacitor C2 and the amplifier 140 can be integrated in an integrated circuit IC. The first detection terminal 110 and the second detection terminal 120 can be coupled to a panel P.

The first switch 131 and the second switch 132 can be turned on alternatively. In other words, when one of the first switch 131 and the second switch 132 is turned on, the other one is turned off.

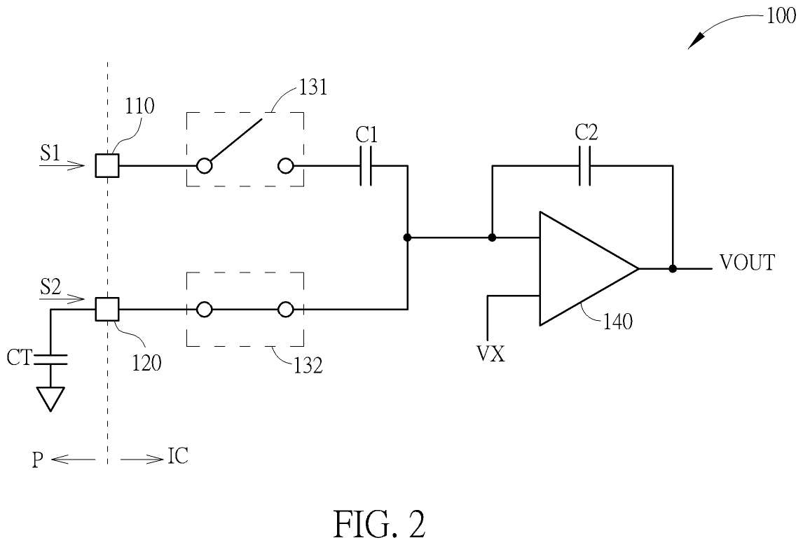

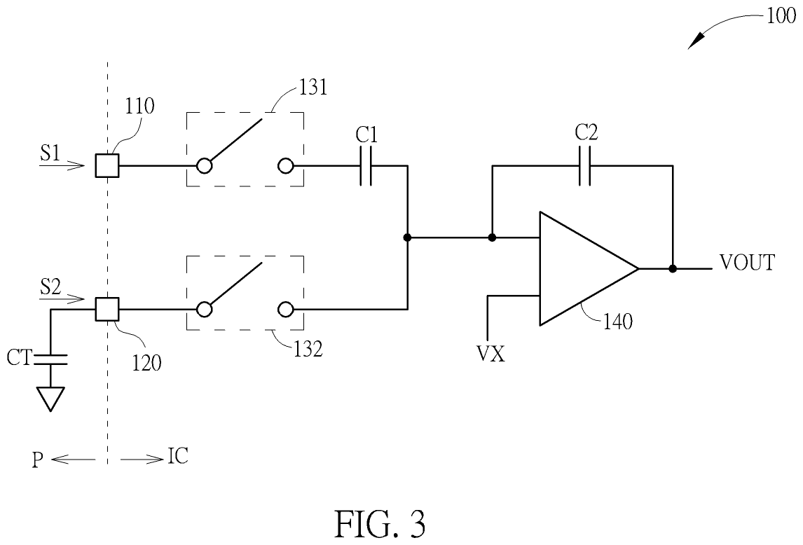

FIG. 2 and FIG. 3 illustrate other operation modes of the detection circuit 100. In FIG. 1 to FIG. 3, the first signal S1 can be a fingerprint detection signal, and the second signal S2 can be a touch detection signal.

In FIG. 1, the first switch 131 is tuned on, the second switch 132 is turned off, and the detection circuit 100 can perform fingerprint detection. In FIG. 2, the first switch 131 is tuned off, the second switch 132 is turned on, and the detection circuit 100 can perform touch detection. In FIG. 3, the first switch 131 and the second switch 132 are turned off, and the panel P can perform the display function.

In FIG. 1, when the first switch 131 is turned on for the detection circuit 100 to perform fingerprint detection, the first signal S1 can be corresponding to a fingerprint of a user, and the output signal VOUT can be corresponding to a ratio of a capacitance of the first capacitor C1 to a capacitance of the second capacitor C2, where the ratio can be expressed as C1/C2. In other words, the amplifier 140 can generate the output signal VOUT according to the ratio C1/C2. For example, the ratio C1/C2 can be between 0.1 and 10.

The touch electrode of the panel P can have an inductive capacitance CT. The change of the second signal S2 can be corresponding to the change of the inductive capacitance CT. In FIG. 2, when the second switch 132 is turned on, the output signal VOUT can be corresponding to the change of the inductive capacitance CT.

The structure in FIG. 1 to FIG. 3 is used for describing the concept of embodiments. For circuit optimization, electrostatic discharge protection, or improvement of reliability, if additional passive components are coupled between the components in FIG. 1 to FIG. 3, or a switch is replaced with multiple switches coupled to one another to improve the driving ability, such reasonable modifications are still within the scope of embodiments.

The first switch 131 and the second switch 132 can be transistor switches. For an N-type transistor switch, a high voltage can be applied to turn on the switch, and a low voltage can be applied to turn off the switch. For a P-type transistor, a low voltage can be applied to turn on the switch, and a high voltage can be applied to turn off the switch.

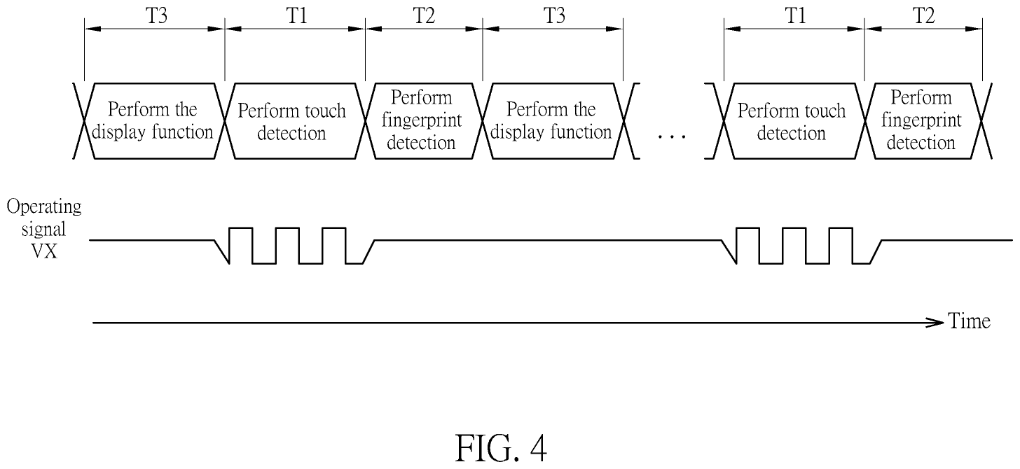

FIG. 4 illustrates the operation modes and the waveform of the operating signal VX of the detection circuit 100 shown in FIG. 1 to FIG. 3. As shown in FIG. 4 and FIG. 2, during the first period T1, the detection circuit 100 can perform touch detection, the second switch 132 can be turned on, and the operating signal VX can substantially have an alternating-current (AC) waveform. The AC waveform can be a square waveform, a sinusoidal waveform, a triangular waveform, a sawtooth waveform, or another kind of AC waveform.

As shown in FIG. 4 and FIG. 1, during the second period T2, the detection circuit 100 can perform fingerprint detection, the first switch 131 can be turned on, and the operating signal VX can be substantially fixed to a predetermined signal level.

As shown in FIG. 4 and FIG. 3, during the third period T3, the detection circuit 100 can perform neither fingerprint detection nor touch detection, and the panel P can perform the display function. When the panel P is performing the display function, at least the first switch 131 can be turned off, and the operating signal VX can be substantially fixed to the predetermined signal level. The abovementioned predetermined signal level can be a direct-current (DC) reference voltage.

If the detection circuit 100 is used with a TDDI (touch and display driver integration) module, because some signals can be used for both of touch detection and the display function, the first switch 131 and the second switch 132 are turned off when the display function is performed during the third period T3. FIG. 3 is an example where the detection circuit 100 is applied with a TDDI module, and FIG. 3 is an example instead of limiting the scope of embodiments.

If the detection circuit 100 is not used with a TDDI module, since touch detection can be performed when the panel P is displaying images, the second switch 132 for touch detection can be turned on during the third period T3 while the first switch 131 for fingerprint detection is turned off.

In FIG. 4, during the first period T1, the AC waveform of the operating signal VX is a square waveform as an example. Embodiments are not limited thereto, and other kinds of AC waveforms can be used.

When touch detection is performed during the first period T1, the AC waveform of the operating signal VX can be equivalently regarded as being applied on the inductive capacitance CT of the panel P. When a finger of a user touches the panel P, the inductive capacitance CT will slightly change, and the ratio of the inductive capacitance CT and the capacitance of the second capacitor C2 will change accordingly. Hence, the signal level of the output signal VOUT can be detected during the first period T1 to determine if the panel P is touched.

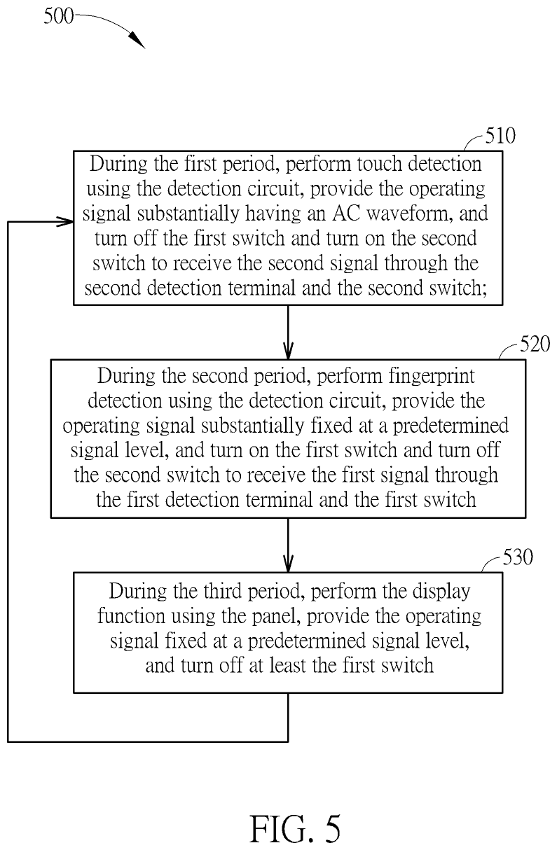

FIG. 5 is a flowchart of a control method 500 for the detection circuit 100 according to an embodiment. The control method 500 can include the following steps.

Step 510: during the first period T1, perform touch detection using the detection circuit 100, provide the operating signal VX substantially having an AC waveform, and turn off the first switch 131 and turn on the second switch 132 to receive the second signal S2 through the second detection terminal 120 and the second switch 132;

Step 520: during the second period T2, perform fingerprint detection using the detection circuit 100, provide the operating signal VX substantially fixed at a predetermined signal level, and turn on the first switch 131 and turn off the second switch 132 to receive the first signal S1 through the first detection terminal 110 and the first switch 131; and

Step 520: during the third period T3, perform the display function using the panel P, provide the operating signal VX fixed at a predetermined signal level, and turn off at least the first switch 131.

Steps 510, 520 and 530 can be cyclically performed. In other words, Step 510 can be performed after Step 530.

The sequence of Steps 510, 520 and 530 in FIG. 5 is an example, and embodiments are not limited thereto. The sequence can be adjusted according to requirements.

In the second period T2 and the third period T3, the predetermined signal levels of the operating signal VX can be the same or be adjusted to be different according to requirements.

In summary, the detection circuit 100 and the control method 500 provide solutions to integrate the circuit and the control method for touch detection and fingerprint detection. As a result, the circuit complexity and the circuit area are reduced, less design resource is required, the user interface is integrated, and the design flexibility is improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A detection circuit, comprising:
a first detection terminal configured to receive a first signal;
a second detection terminal configured to receive a second signal;
a first switch coupled to the first detection terminal;
a second switch coupled to the second detection terminal;
a first capacitor coupled to the first switch and the second switch;
an amplifier comprising a first input terminal coupled to the first capacitor, a second input terminal configured to receive an operating signal, and an output terminal configured to output an output signal; and
a second capacitor coupled between the first input terminal and the output terminal of the amplifier;
wherein the first switch and the second switch are turned on alternatively.

2. The detection circuit of claim 1, wherein the first signal is a fingerprint detection signal, and the second signal is a touch detection signal.

3. The detection circuit of claim 1, wherein the output signal is corresponding to a ratio of a capacitance of the first capacitor to a capacitance of the second capacitor when the first switch is turned on.

4. The detection circuit of claim 1, wherein the second detection terminal is coupled to a panel, and a change of the second signal is corresponding to a change of an inductive capacitance of a touch electrode of the panel.

5. The detection circuit of claim 4, wherein the output signal is corresponding to the change of the inductive capacitance when the second switch is turned on.

6. The detection circuit of claim 1, wherein the operating signal is substantially fixed to a predetermined signal level when the first switch is turned on.

7. The detection circuit of claim 1, wherein the operating signal substantially has an alternating-current (AC) waveform when the second switch is turned on.

8. The detection circuit of claim 7, wherein the alternating-current waveform is a square waveform, a sinusoidal waveform, a triangular waveform or a sawtooth waveform.

9. A control method for a detection circuit, the detection circuit comprising a first detection terminal, a second detection terminal, a first switch, a second switch, a first capacitor, a second capacitor and an amplifier, the first switch being coupled between the first detection terminal and the first capacitor, the second switch being coupled between the second detection terminal and the first capacitor, the first capacitor being coupled between the first switch and a first input terminal of the amplifier, the second capacitor being coupled between the first input terminal and an output terminal of the amplifier, a second input terminal of the amplifier being used for receiving an operating signal, the control method comprising:
turning off the first switch and turning on the second switch for receiving a second signal through the second detection terminal and the second switch during a first period; and
turning on the first switch and turning off the second switch for receiving a first signal through the first detection terminal and the first switch during a second period.

10. The control method of claim 9, further comprising:
providing the operating signal substantially having an alternating-current (AC) waveform during the first period; and
providing the operating signal fixed at a predetermined signal level during the second period.

11. The control method of claim 9, further comprising:
turning off the first switch and fixing the operating signal to a predetermined signal level during a third period.
